(19) United States
(12) Patent Application Publication
(10) Pub. No.: US 2025/0275451 A1
(43) Pub. Date: Aug. 28, 2025

(54) DISPLAY DEVICE AND ELECTRONIC DEVICE INCLUDING THE SAME

(71) Applicant: Samsung Display Co., LTD., Yongin-si (KR)

(72) Inventors: YONGSUB SHIM, Yongin-si (KR); JEWON YOO, Yongin-si (KR); JUNGMIN CHOI, Yongin-si (KR); JONGBEOM HONG, Yongin-si (KR)

(21) Appl. No.: 18/970,729

(22) Filed: Dec. 5, 2024

(30) Foreign Application Priority Data
Feb. 26, 2024 (KR) 10-2024-0027388

(51) Int. Cl. H10K 59/80; H10K 59/38

(52) U.S. Cl. CPC H10K 59/8792; H10K 59/38; H10K 59/879

(57) ABSTRACT

A display device includes a substrate, a pixel electrode above the substrate, and having an upper surface tilted by an angle with respect to a plane of the substrate, a light-emitting layer above the pixel electrode, and a light control layer above the light-emitting layer, and including a first light-blocking pattern, and a second light-blocking pattern above the first light-blocking pattern and shifted in a first direction from the first light-blocking pattern.

### CROSS-REFERENCE TO RELATED APPLICATION

The present application claims priority to, and the benefit of, Korean Patent Application No. 10-2024-0027388, filed on Feb. 26, 2024, in the Korean Intellectual Property Office, the entire disclosure of which is incorporated herein by reference.

### BACKGROUND

### 1. Field

The present disclosure relates to a display device that provides visual information. The present disclosure relates to an electronic device including the display device.

### 2. Description Of The Related Art

With the development of information technology, the importance of a display device, which is a connection medium between a user and information, has been highlighted. For example, the use of display devices, such as liquid crystal display (“LCD”) device, organic light-emitting diode (“OLED”) display device, plasma display panel (“PDP”), quantum dot display device or the like is increasing.

In general, a display device is manufactured to have a wide viewing angle, but the viewing angle may need to be limited for reasons, such as privacy, protection of information, etc. For example, devices, such as ATMs of financial institution, laptops, tablet PCs, etc. may require a limited viewing angle to protect privacy.

When a display device is applied to an automobile, if the display device has

a wide viewing angle, an image displayed on the display device may be reflected from a front windshield of the automobile and may interfere with the driver's operation. Accordingly, much research has been conducted to adjust the viewing angle of the display device.

### SUMMARY

Embodiments provide a display device with adjustable viewing angle.

Embodiments provide an electronic device including the display device.

A display device according to one or more embodiments of the present disclosure includes a substrate, a pixel electrode above the substrate, and having an upper surface tilted by an angle with respect to a plane of the substrate, a light-emitting layer above the pixel electrode, and a light control layer above the light-emitting layer, and including a first light-blocking pattern, and a second light-blocking pattern above the first light-blocking pattern and shifted in a first direction from the first light-blocking pattern.

A second normal line of the upper surface of the pixel electrode may be tilted by a first angle in the first direction with respect to a first normal line of the plane, wherein a side surface of the second light-blocking pattern is shifted in the first direction from a side surface of the first light-blocking pattern, and wherein an imaginary straight line connecting the side surface of the first light-blocking pattern and the side surface of the second light-blocking pattern is tilted by a second angle in the first direction with respect to the first normal line.

A difference between the first angle and the second angle may be about 0 degrees to about 2 degrees.

The light control layer may further include a third light-blocking pattern above the second light-blocking pattern and shifted in the first direction from the second light-blocking pattern.

A first interval at which the second light-blocking pattern is shifted from the first light-blocking pattern may be substantially equal to a second interval at which the third light-blocking pattern is shifted from the second light-blocking pattern.

The display device may further include a via-insulating layer between the substrate and the pixel electrode, and including an inclined surface tilted by an angle with respect to the plane.

The display device may further include a sensing pattern between the light-

emitting layer and the light control layer, and including a metal, wherein the sensing pattern is shifted in a direction opposite to the first direction from the first light-blocking pattern.

The light control layer may further include a micro lens portion overlapping the light-emitting layer in a plan view.

The first light-blocking pattern may be provided in plural, the first light-blocking patterns being spaced apart from each other in the first direction with the micro lens portion interposed therebetween.

The second light-blocking pattern may be provided in plural, the second light-blocking patterns being spaced apart from each other in the first direction with the micro lens portion interposed therebetween.

The display device may further include a color filter layer between the light-emitting layer and the light control layer, and including a first color filter, a second color filter, and a third color filter that transmit light of different respective colors, and that have respective overlapping portions to form an overlapping pattern that is shifted in a direction opposite to the first direction from the first light-blocking pattern.

The light-emitting layer may have a light-emitting surface that is tilted by an angle with respect to the plane, and that is substantially parallel to the upper surface of the pixel electrode.

The first light-blocking pattern and the second light-blocking pattern may partially overlap in a plan view.

A length in the first direction of the first light-blocking pattern may be substantially equal to a length in the first direction of the second light-blocking pattern.

A display device according to one or more other embodiments of the present disclosure includes a substrate, a pixel electrode above the substrate, and having an upper surface tilted by an angle with respect to a plane of the substrate, a light-emitting layer above the pixel electrode, and a light control layer above the light-emitting layer, and including a light-blocking pattern having a side surface tilted in a first direction with respect to a first normal line of the plane.

A second normal line of the upper surface of the pixel electrode may be tilted by a first angle in the first direction with respect to the first normal line, wherein the side surface of the light-blocking pattern is tilted by a second angle in the first direction with respect to the first normal line.

A difference between the first angle and the second angle may be about 0 degrees to about 2 degrees.

The display device may further include a via-insulating layer between the substrate and the pixel electrode, and including an inclined surface tilted by an angle with respect to the plane.

The light control layer may further include a micro lens portion overlapping the light-emitting layer in a plan view, wherein the light-blocking pattern is provided in plural, the light-blocking patterns being spaced apart from each other in the first direction with the micro lens portion interposed therebetween.

The light-emitting layer may have a light-emitting surface that is tilted by an angle with respect to the plane, and is substantially parallel to the upper surface of the pixel electrode.

An electronic device according to one or more embodiments of the present disclosure includes a display device and a power supply configured to provide power to the display device. The display device includes a substrate, a pixel electrode above the substrate, and having an upper surface tilted by an angle with respect to a plane of the substrate, a light-emitting layer above the pixel electrode, and a light control layer above the light-emitting layer, and including a first light-blocking pattern, and a second light-blocking pattern above the first light-blocking pattern and shifted in a first direction from the first light-blocking pattern.

A display device according to one or more embodiments of the present disclosure may include a light-emitting layer having a light-emitting surface that is tilted by an angle (e.g., a predetermined angle) with respect to a horizontal plane of a substrate, and a light control layer located on the light-emitting layer and including a first light-blocking pattern and a second light-blocking pattern located on the first light-blocking pattern and shifted in one direction from the first light-blocking pattern. An imaginary straight line connecting a side surface of the first light-blocking pattern and a side surface of the second light-blocking pattern may be tilted by a specific angle in the one direction with respect to a first normal line of the horizontal plane.

Accordingly, the display device may have a maximum luminance at a specific viewing angle, and the viewing angle of the display device may be adjusted in the one direction and in a direction opposite to the one direction.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to a first one or more embodiments of the present disclosure.

FIG. 2 is an enlarged plan view of the area A of FIG. 1.

FIG. 3 is a cross-sectional view illustrating the display device of FIG. 1.

FIG. 4 is a cross-sectional view taken along the line I-I′ of FIG. 2.

FIG. 5 is a cross-sectional view illustrating a path of light traveling in the display device of FIG. 4.

FIGS. 6 and 7 are cross-sectional views illustrating a display device according to a second one or more embodiments of the present disclosure.

FIGS. 8 and 9 are cross-sectional views illustrating a display device according to a third one or more embodiments of the present disclosure.

FIGS. 10 and 11 are cross-sectional views illustrating a display device according to a fourth one or more embodiments of the present disclosure.

FIGS. 12 and 13 are cross-sectional views illustrating a display device according to a fifth one or more embodiments of the present disclosure.

FIG. 14 is a cross-sectional view illustrating a path of light traveling in the display device of FIG. 13.

FIG. 15 is a block diagram illustrating an electronic device according to one or more embodiments of the present disclosure.

FIG. 16 is a view illustrating an example of the electronic device of FIG. 15 is implemented as a window of automobile.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

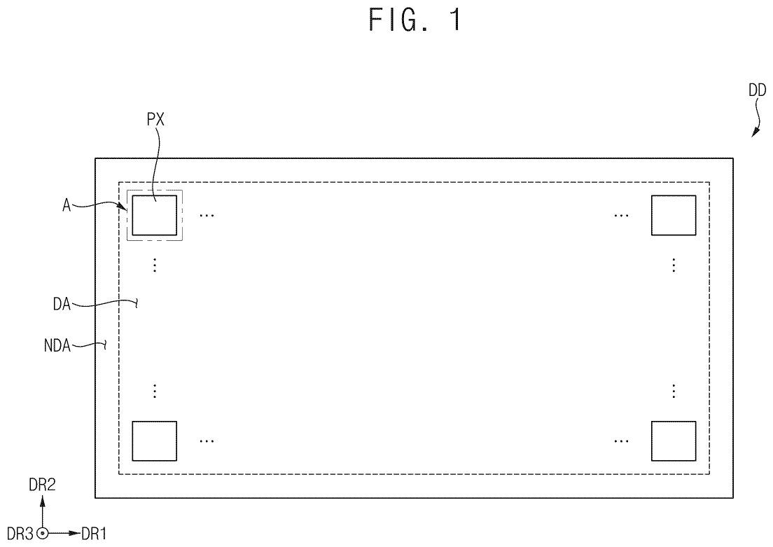

FIG. 1 is a plan view illustrating a display device according to a first one or more embodiments of the present disclosure.

In this specification, a plane may be defined by a first direction DR1, and by a second direction DR2 intersecting the first direction DR1. For example, the first direction DR1 and the second direction DR2 may be substantially perpendicular to each other. The first direction DR1 and a direction opposite to the first direction DR1 may refer to a left-right direction (or a horizontal direction) in a plan view. For example, the first direction DR1 may refer to a right direction in a plan view, and the direction opposite to the first direction DR1 may refer to a left direction in a plan view. The second direction DR2 and a direction opposite to the second direction DR2 may refer to an up-down direction (or a vertical direction) in a plan view. For example, the second direction DR2 may refer to an upward direction in a plan view, and the direction opposite to the second direction DR2 may refer to a downward direction in a plan view. A direction normal to the plane may be a third direction DR3. In other words, the third direction DR3 may be substantially perpendicular to each of the first direction DR1 and the second direction DR2. The third direction DR3 may refer to a front direction of a display device DD.

Referring to FIG. 1, the display device DD according to a first one or more embodiments of the present disclosure may include a display area DA and a non-display area NDA.

The display area DA may be defined as an area that may display an image by generating light, or by adjusting the transmittance of light provided from an external light source. A plurality of pixels PX may be located in the display area DA. The pixels PX may generate light in response to a driving signal. The pixels PX may be arranged repeatedly along the first direction DR1 and the second direction DR2 in the display area DA.

In one or more embodiments, the display area DA may have a rectangular planar shape. For example, a length in the first direction DR1 of the display area DA may be greater than a length in the second direction DR2 of the display area DA. For another example, the length in the second direction DR2 of the display area DA may be greater than the length in the first direction DR1 of the display area DA. However, the planar shape of the display area DA is not limited thereto. For example, the display area DA may have any one of a square planar shape, a circular planar shape, an elliptical planar shape, and an oval planar shape.

The non-display area NDA may be defined as an area that does not display an image. For example, the non-display area NDA may entirely surround the display area DA (e.g., in plan view). A driving chip and a plurality of pads that provide the driving signal to the pixels PX may be located in the non-display area NDA.

Although a display device is generally manufactured to have a wide viewing angle, it may be suitable to have a limited viewing angle depending on a product to which the display device is applied. For example, when the display device is applied to an automobile, if the display device has a wide viewing angle, an image displayed on the display device may be reflected from a front windshield of the automobile, and may interfere with the driver's operation.

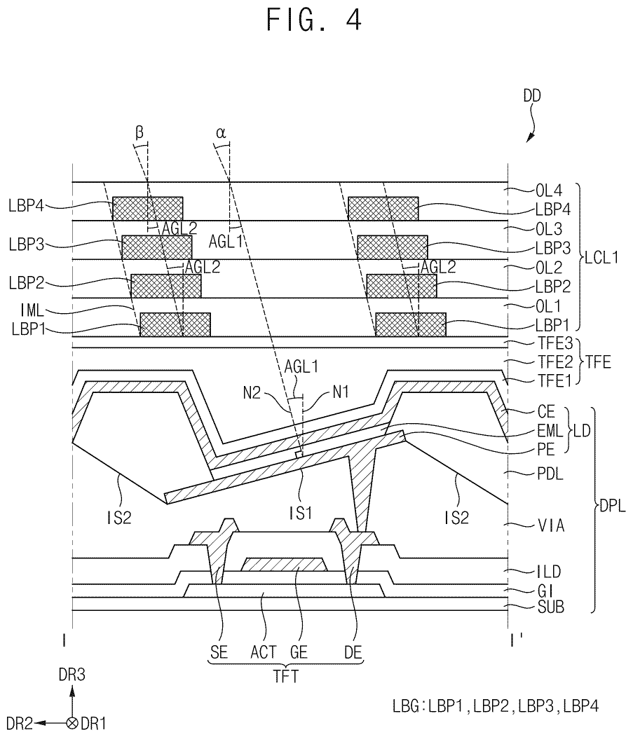

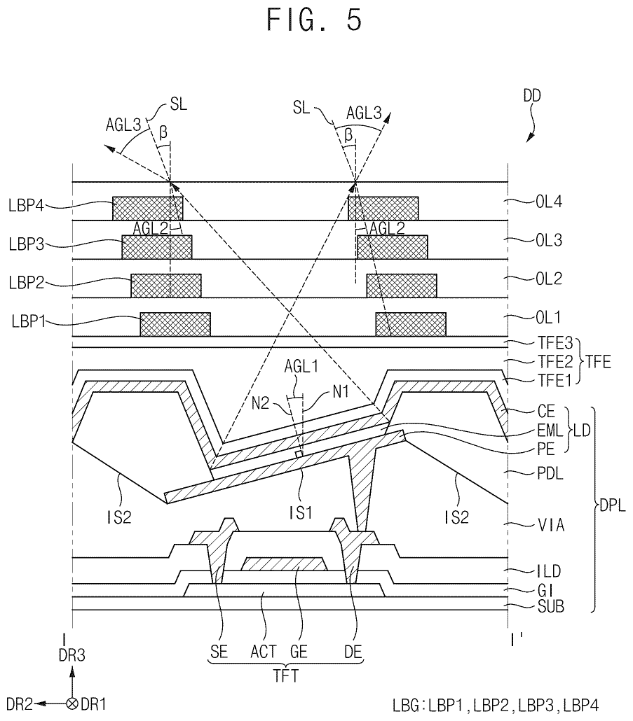

The display device DD according to the first one or more embodiments of the present disclosure may include a plurality of light-blocking patterns (e.g., first to fourth light-blocking patterns LBP1, LBP2, LBP3, and LBP4 of FIG. 4). Accordingly, the viewing angle of the display device DD may be adjusted. A detailed description of this will be described below with reference to FIG. 5.

In one or more embodiments, the display device DD may be applied to an automotive display device. However, the present disclosure is not limited thereto, and the display device DD may be applied to various display devices that require adjustment of the viewing angle.

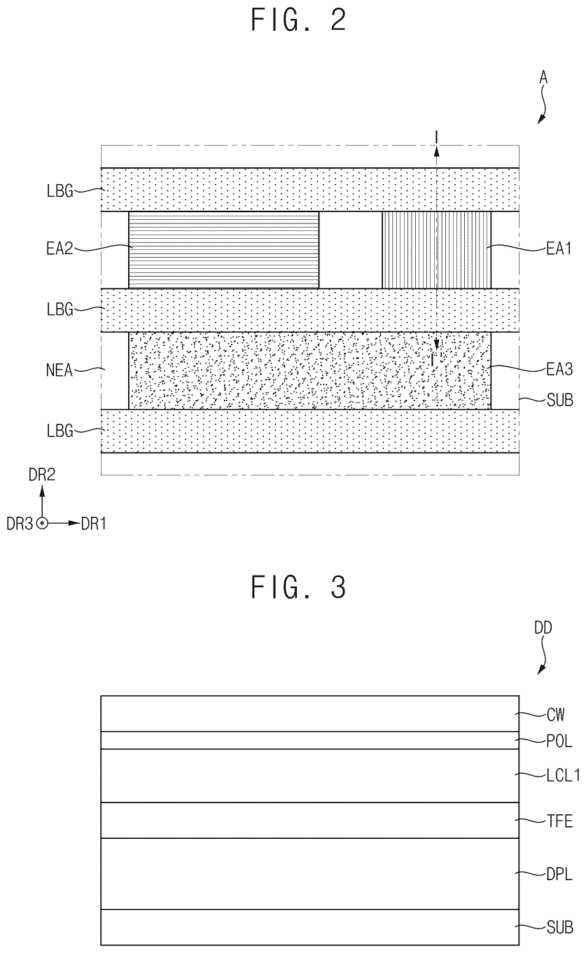

FIG. 2 is an enlarged plan view of the area A of FIG. 1.

Referring to FIGS. 1 and 2, the display device DD according to the first one or more embodiments of the present disclosure may include a substrate SUB, the plurality of pixels PX, and a plurality of light-blocking pattern groups LBG in the display area DA.

The pixels PX may be repeatedly arranged along the first direction DR1 and the second direction DR2 in the display area DA on the substrate SUB. Each of the pixels PX may include a first sub-pixel, a second sub-pixel, and a third sub-pixel. The first sub-pixel may generate light of a first color, the second sub-pixel may generate light of a second color, and the third sub-pixel may generate light of a third color. For example, the first color may be red, the second color may be green, and the third color may be blue, but the present disclosure is not limited thereto.

Each of the pixels PX may include a first light-emitting area EA1, a second light-emitting area EA2, and a third light-emitting area EA3. For example, the first sub-pixel may include the first light-emitting area EA1, the second sub-pixel may include the second light-emitting area EA2, and the third sub-pixel may include the third light-emitting area EA3. Each of the first to third light-emitting areas EA1, EA2, and EA3 may be defined as an area where light is emitted.

For example, each of the first to third light-emitting areas EA1, EA2, and EA3 may have a rectangular planar shape. However, the present disclosure is not limited thereto. For another example, each of the first to third light-emitting areas EA1, EA2, and EA3 may have any one of a triangular planar shape, a circular planar shape, and an elliptical planar shape.

Light of the first color may be emitted from the first light-emitting area EA1. That is, a light-emitting element that emits light of the first color may be located in the first light-emitting area EA1. Light of the second color may be emitted from the second light-emitting area EA2. That is, a light-emitting element that emits light of the second color may be located in the second light-emitting area EA2. Light of the third color may be emitted from the third light-emitting area EA3. That is, a light-emitting element that emits light of the third color may be located in the third light-emitting area EA3.

In one or more embodiments, a size (or, an area) of the third light-emitting area EA3 may be greater than a size of the second light-emitting area EA2. In addition, the size of the second light-emitting area EA2 may be greater than a size of the first light-emitting area EA1. However, the present disclosure is not limited thereto, and the first to third light-emitting areas EA1, EA2, and EA3 may have the same size as each other.

In one or more embodiments, the first light-emitting area EA1 and the second light-emitting area EA2 may be located in the same row, and the third light-emitting area EA3 may be located in a different row from the first light-emitting area EA1 and the second light-emitting area EA2. The third light-emitting area EA3 may be spaced apart from the first light-emitting area EA1 and the second light-emitting area EA2 in the second direction DR2 with the light-blocking pattern group LBG therebetween.

A length in the second direction DR2 of the first light-emitting area EA1, a length in the second direction DR2 of the second light-emitting area EA2, and a length in the second direction DR2 of the third light-emitting area EA3 may be substantially equal to each other.

A non-emission area NEA may be defined as an area that does not emit light. For example, the non-emission area NEA may surround the first to third light-emitting areas EA1, EA2, and EA3 in a plan view.

The light-blocking pattern groups LBG may be located in the display area DA on the substrate SUB. The light-blocking pattern groups LBG may be repeatedly arranged along the second direction DR2 in the display area DA. The light-blocking pattern groups LBG may be spaced apart from each other at equal intervals in the second direction DR2. Each of the light-blocking pattern groups LBG may extend in the first direction DR1. Each of the light-blocking pattern groups LBG may include a plurality of light-blocking patterns (e.g., first to fourth light-blocking patterns LBP1, LBP2, LBP3, and LBP4 of FIG. 4). Accordingly, the light-blocking pattern groups LBG may adjust the viewing angle in the second direction DR2 and in the direction opposite to the second direction DR2. For example, the light-blocking pattern groups LBG may adjust the viewing angle in the up-down direction. A detailed description of this will be described below with reference to FIG. 5.

FIG. 3 is a cross-sectional view illustrating the display device of FIG. 1.

Referring to FIG. 3, the display device DD according to the first one or more embodiments of the present disclosure may include the substrate SUB, a display element layer DPL, an encapsulation layer TFE, a first light control layer LCL1, a polarization layer POL, and a cover window CW.

The substrate SUB may include a transparent material or an opaque material. In one or more embodiments, the substrate SUB may be formed of a transparent resin substrate. A polyimide substrate may be an example of the transparent resin substrate. In this case, the polyimide substrate may include a first organic layer, a first barrier layer, a second organic layer, etc. In one or more embodiments, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The display element layer DPL may be located on the substrate SUB (as used herein, “located on” may mean “above”). The display element layer DPL may include a thin film transistor that generates a driving current, and a light-emitting element that emits light. The light-emitting element may be electrically connected to the thin film transistor, and may be provided with the driving current. The light-emitting element may emit light in response to the driving current. A detailed description thereof will be described below with reference to FIG. 4.

The encapsulation layer TFE may be located on the display element layer DPL. The encapsulation layer TFE may protect the display element layer DPL from external impurities, moisture, etc.

The first light control layer LCL1 may be located on the encapsulation layer TFE. The first light control layer LCL1 may include a plurality of transmission layers and a plurality of light-blocking patterns. The light-blocking patterns may block light that is refracted at an angle that is greater than an angle (e.g., a predetermined angle). The transmission layers may transmit light that is refracted at an angle that is less than or equal to the angle (e.g., the predetermined angle) to the outside of the display device DD. Accordingly, the viewing angle of the display device DD may be adjusted. A detailed description of this will be described below with reference to FIGS. 4 and 5.

The polarization layer POL may be located on the first light control layer LCL1. The polarization layer POL may polarize an external light. In other words, the polarization layer POL may reduce the external light reflection of the display device DD. As the external light reflection is reduced, the visibility of the display device DD may be improved.

The cover window CW may be located on the polarization layer POL. The cover window CW may include a transparent material to allow light provided by the light-emitting element to pass to the outside. The cover window CW may protect the display element layer DPL, the first light control layer LCL1, etc. from an external force.

FIG. 4 is a cross-sectional view taken along the line I-I′ of FIG. 2. For example, FIG. 4 is a cross-sectional view illustrating a cross-section of the first sub-pixel in the first light-emitting area EA1 of FIG. 2 cut in the second direction DR2. FIG. 5 is a cross-sectional view illustrating a path of light traveling in the display device of FIG. 4.

In FIG. 2, the cross-section of the first sub-pixel in the first light-emitting area EA1 cut in the second direction DR2 may have a shape substantially the same or symmetrical to a cross-section of the second sub-pixel in the second light-emitting area EA2 cut in the second direction DR2 and a cross-section of the third sub-pixel in the third light-emitting area EA3 cut in the second direction DR2. Hereinafter, the description will focus on the cross-section of the first sub-pixel in the first light-emitting area EA1 cut in the second direction DR2

Referring to FIG. 4, the display device DD according to the first one or more embodiments of the present disclosure may include the substrate SUB, the display element layer DPL, the encapsulation layer TFE, and the first light control layer LCL1. The display element layer DPL may include a thin film transistor TFT, a gate-insulating layer GI, an inter-layer insulating layer ILD, a via-insulating layer VIA, a light-emitting element LD, and a pixel-defining layer PDL. The thin film transistor TFT may include an active pattern ACT, a gate electrode GE, a source electrode SE, and a drain electrode DE. The light-emitting element LD may include a pixel electrode PE, a light-emitting layer EML, and a common electrode CE.

The active pattern ACT may be located on the substrate SUB. The active pattern ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These may be used alone or in combination with each other. The silicon semiconductor may include amorphous silicon, polycrystalline silicon, etc. The active pattern ACT may include a source area, a drain area, and a channel area positioned between the source area and the drain area.

The gate-insulating layer GI may be located on the active pattern ACT and the substrate SUB. In one or more embodiments, the gate-insulating layer GI may cover the active pattern ACT on the substrate SUB, and may be located along the profile of the active pattern ACT with a substantially uniform thickness. In one or more embodiments, the gate-insulating layer GI may sufficiently cover the active pattern ACT on the substrate SUB, and may have a substantially flat upper surface without creating a step difference around the active pattern ACT. The gate-insulating layer GI may include an inorganic insulating material. Examples of the inorganic insulating material that may be used as the gate-insulating layer GI may include silicon oxide (SiOₓ), silicon nitride (SiNₓ), silicon oxynitride (SiOₓN_{y}), etc. These may be used alone or in combination with each other. The gate-insulating layer GI may electrically insulate the active pattern ACT from the gate electrode GE.

The gate electrode GE may be located on the gate-insulating layer GI. The gate electrode GE may overlap the channel area of the active pattern ACT in a plan view. The gate electrode GE may include a metal, an alloy, a metal nitride, a conductive metal oxide, a transparent conductive material, etc. Examples of material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other.

The inter-layer insulating layer ILD may be located on the gate electrode GE and the gate-insulating layer GI. In one or more embodiments, the inter-layer insulating layer ILD may cover the gate electrode GE on the gate-insulating layer GI, and may be located along the profile of the gate electrode GE with a substantially uniform thickness. In one or more embodiments, the inter-layer insulating layer ILD may sufficiently cover the gate electrode GE on the gate-insulating layer GI, and may have a substantially flat upper surface without creating a step difference around the gate electrode GE. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), etc. These may be used alone or in combination with each other. The inter-layer insulating layer ILD may electrically insulate the gate electrode GE from the source electrode SE. In addition, the inter-layer insulating layer ILD may electrically insulate the gate electrode GE from the drain electrode DE.

The source electrode SE and the drain electrode DE may be located on the inter-layer insulating layer ILD. The source electrode SE may be connected to the source area of the active pattern ACT through a contact hole formed through the gate-insulating layer GI and the inter-layer insulating layer ILD. The drain electrode DE may be connected to the drain area of the active pattern ACT through a contact hole formed through the gate-insulating layer GI and the inter-layer insulating layer ILD. Each of the source electrode SE and the drain electrode DE may include a metal, an alloy, a metal nitride, a conductive metal oxide, a transparent conductive material, etc. These may be used alone or in combination with each other.

Accordingly, the thin film transistor TFT including the active pattern ACT, the gate electrode GE, the source electrode SE, and the drain electrode DE may be formed.

The via-insulating layer VIA may be located on the inter-layer insulating layer ILD. For example, the via-insulating layer VIA may be located on the inter-layer insulating layer ILD with a relatively thick thickness to sufficiently cover the source electrode SE and the drain electrode DE. The via-insulating layer VIA may include an organic insulating material. Examples of the organic insulating material that may be used as the via-insulating layer VIA may include a photoresist, a polyacryl-based resin, a polyimide-based resin, a polyamide-based resin, a siloxane-based resin, an acryl-based resin, an epoxy-based resin, etc. These may be used alone or in combination with each other.

The via-insulating layer VIA may include an inclined surface tilted by an angle (e.g., a predetermined angle) with respect to a horizontal plane of the substrate SUB. For example, the via-insulating layer VIA may include a first inclined surface IS1 tilted in a counterclockwise direction with respect to the horizontal plane, and a second inclined surface IS2 tilted in a clockwise direction with respect to the horizontal plane. The first inclined surface IS1 may contact the second inclined surface IS2. The first inclined surface IS1 and the second inclined surface IS2 may be alternately located along the second direction DR2. For example, an angle at which the first inclined surface IS1 is tilted in the counterclockwise direction with respect to the horizontal plane may be the same as an angle at which the second inclined surface IS2 is tilted in the clockwise direction with respect to the horizontal plane. For another example, the angle at which the first inclined surface IS1 is tilted in the counterclockwise direction with respect to the horizontal plane may be different from the angle at which the second inclined surface IS2 is tilted in the clockwise direction with respect to the horizontal plane.

The pixel electrode PE may be located on the via-insulating layer VIA. The pixel electrode PE may be electrically connected to the drain electrode DE through a contact hole formed through the via-insulating layer VIA. Accordingly, the pixel electrode PE may be electrically connected to the thin film transistor TFT. For example, the pixel electrode PE may be a semi-transmissive electrode, a transmissive electrode, or a reflective electrode. The pixel electrode PE may include a metal, an alloy, a metal nitride, a conductive metal oxide, a transparent conductive material, etc. These may be used alone or in combination with each other. For example, the pixel electrode PE may serve as an anode electrode.

The pixel electrode PE may be located on the first inclined surface IS1 of the via-insulating layer VIA. Accordingly, the pixel electrode PE may have an upper surface tilted by an angle (e.g., a predetermined angle) with respect to the horizontal plane of the substrate SUB. The upper surface of the pixel electrode PE may be located substantially parallel to the first inclined surface IS1 of the via-insulating layer VIA.

In one or more embodiments, a second normal line N2 of the upper surface of the pixel electrode PE may be tilted by a first angle AGL1 in the second direction DR2 with respect to a first normal line N1 of the horizontal plane. The first normal line N1 is perpendicular to the horizontal plane, and the second normal line N2 is perpendicular to the upper surface of the pixel electrode PE.

The pixel-defining layer PDL may be located on the via-insulating layer VIA and the pixel electrode PE. For example, the pixel-defining layer PDL may overlap the second inclined surface IS2 of the via-insulating layer VIA and an edge of the pixel electrode PE. The pixel-defining layer PDL may cover the edge of the pixel electrode PE, and may expose the upper surface of the pixel electrode PE. The pixel-defining layer PDL may include an organic insulating material. Examples of the organic insulating material that may be used as the pixel-defining layer PDL may include a photoresist, a polyacryl-based resin, a polyimide-based resin, a polyamide-based resin, a siloxane-based resin, an acryl-based resin, an epoxy-based resin, etc. These may be used alone or in combination with each other.

The light-emitting layer EML may be located on the pixel electrode PE. For example, the light-emitting layer EML may be located on the upper surface of the pixel electrode PE exposed by the pixel-defining layer PDL. The light-emitting layer EML may have a light-emitting surface (or, an upper surface) parallel to the upper surface of the pixel electrode PE. As the upper surface of the pixel electrode PE is tilted by an angle (e.g., a predetermined angle) with respect to the horizontal plane, the light-emitting surface of the light-emitting layer EML may be tilted by an angle (e.g., a predetermined angle) with respect to the horizontal plane.

As the light-emitting surface of the light-emitting layer EML is located substantially parallel to the upper surface of the pixel electrode PE, a third normal line of the light-emitting surface may be substantially parallel to the second normal line N2. In other words, the third normal line of the light-emitting surface may be tilted by an angle substantially equal to the first angle AGL1 in the second direction DR2 with respect to the first normal line N1. The third normal line is perpendicular to the light-emitting surface.

The light-emitting layer EML may emit light having a corresponding color. For example, the light-emitting layer EML may emit light of the first color in the first light-emitting area. For example, the first color may be red, but the present disclosure is not limited thereto. In one or more embodiments, the light-emitting layer EML may include one or both of an organic light-emitting material and a quantum dot.

The common electrode CE may be located on the pixel-defining layer PDL and the light-emitting layer EML. The common electrode CE may cover the pixel-defining layer PDL and the light-emitting layer EML, and may be located along the profiles of the pixel-defining layer PDL and the light-emitting layer EML with a substantially uniform thickness. Accordingly, a portion of the common electrode CE overlapping the light-emitting layer EML may be tilted by an angle (e.g., a predetermined angle) with respect to the horizontal plane. The common electrode CE may include a metal, an alloy, a metal nitride, a conductive metal oxide, a transparent conductive material, etc. They may be used alone or in combination with each other. For example, the common electrode CE may serve as a cathode electrode.

Accordingly, the light-emitting element LD including the pixel electrode PE, the light-emitting layer EML, and the common electrode CE may be formed.

Although the display device DD of the present disclosure is described by limiting the organic light-emitting diode (“OLED”) display device, the configuration of the present disclosure is not limited thereto. In other embodiments, the display device DD may include a liquid crystal display (“LCD”) device, a field emission display (“FED”) device, a plasma display panel (“PDP”) device, an electrophoretic image display (“EPD”) device, an inorganic light-emitting diode (“ILED”) display device, or a quantum dot display device.

The encapsulation layer TFE may be located on the common electrode CE. The encapsulation layer TFE may reduce or prevent impurities, moisture, etc. penetrating into the light-emitting element LD from the outside. The encapsulation layer TFE may include at least one inorganic layer and at least one organic layer. For example, the inorganic layer may include silicon oxide (SiOₓ), silicon nitride (SiNₓ), silicon oxynitride (SiOₓN_{y}), etc. These may be used alone or in combination with each other. For example, the organic layer may include a cured polymer, such as polyacrylate.

The encapsulation layer TFE may have a structure in which the inorganic layer and the organic layer are alternately stacked. In one or more embodiments, the encapsulation layer TFE may include a first inorganic encapsulation layer TFE1, an organic encapsulation layer TFE2, and a second inorganic encapsulation layer TFE3.

The first inorganic encapsulation layer TFE1 may be located on the common electrode CE. The first inorganic encapsulation layer TFE1 may cover the common electrode CE, and may be located along the profile of the common electrode CE with a substantially uniform thickness. The first inorganic encapsulation layer TFE1 may reduce or prevent deterioration of the light-emitting element LD due to penetration of impurities, moisture, etc. In addition, the first inorganic encapsulation layer TFE1 may protect the light-emitting element LD from an external impact. For example, the first inorganic encapsulation layer TFE1 may include a flexible inorganic insulating material.

The organic encapsulation layer TFE2 may be located on the first inorganic encapsulation layer TFE1. The organic encapsulation layer TFE2 may improve the flatness of the display device DD. In other words, the organic encapsulation layer TFE2 may flatten a step difference of a lower structure (e.g., the common electrode CE, the first inorganic encapsulation layer TFE1, etc.). The organic encapsulation layer TFE2 may protect the light-emitting element LD from an external impact together with the first inorganic encapsulation layer TFE1. For example, the organic encapsulation layer TFE2 may include a flexible organic material.

The second inorganic encapsulation layer TFE3 may be located on the organic encapsulation layer TFE2. The second inorganic encapsulation layer TFE3 may cover the organic encapsulation layer TFE2, and may be located along the profile of the organic encapsulation layer TFE2 with a substantially uniform thickness. As the organic encapsulation layer TFE2 flattens a step difference of the lower structure, the second inorganic encapsulation layer TFE3 may have a substantially flat upper surface. The second inorganic encapsulation layer TFE3 may reduce or prevent deterioration of the light-emitting element LD due to penetration of impurities, moisture, etc. together with the first inorganic encapsulation layer TFE1. In addition, the second inorganic encapsulation layer TFE3 may protect the light-emitting element LD from an external impact together with the first inorganic encapsulation layer TFE1 and the organic encapsulation layer TFE2. For example, the second inorganic encapsulation layer TFE3 may include a flexible inorganic insulating material.

The first light control layer LCL1 may be located on the encapsulation layer TFE. As illustrated in FIG. 4, the first light control layer LCL1 may include first light-blocking patterns LBP1, a first transmission layer OL1, second light-blocking patterns LBP2, a second transmission layer OL2, third light-blocking patterns LBP3, a third transmission layer OL3, fourth light-blocking patterns LBP4, and a fourth transmission layer OL4.

The first light-blocking patterns LBP1 may be located on the encapsulation layer TFE. The first light-blocking patterns LBP1 may be spaced apart from each other in a second direction (DR2). Some of the first light-blocking patterns LBP1 may be adjacent to the light-emitting layer EML in the second direction DR2 in a plan view. Other portions of the first light-blocking patterns LBP1 may be adjacent to the light-emitting layer EML in the direction opposite to the second direction DR2 in a plan view. The first light-blocking patterns LBP1 may block light.

In this specification, a length in the second direction DR2 of a corresponding configuration may be referred to as a width, and a length in the third direction DR3 of a corresponding configuration may be referred to as a thickness.

In one or more embodiments, a first width of the first light-blocking pattern LBP1 may be greater than a first thickness of the first light-blocking pattern LBP1. However, the present disclosure is not limited thereto, and the first width of the first light-blocking pattern LBP1 may be less than the first thickness of the first light-blocking pattern LBP1.

The first transmission layer OL1 may be located on the encapsulation layer TFE. The first transmission layer OL1 may cover the first light-blocking patterns LBP1, and may have a substantially flat upper surface. The first transmission layer OL1 may have a refractive index that is greater than 1. The first transmission layer OL1 may include an organic material. For example, a thickness of the first transmission layer OL1 may be greater than the first thickness of the first light-blocking pattern LBP1. However, the present disclosure is not limited thereto, and the thickness of the first transmission layer OL1 may be substantially the same as the first thickness of the first light-blocking pattern LBP1.

The second light-blocking patterns LBP2 may be located on the first light-blocking patterns LBP1. For example, the second light-blocking patterns LBP2 may be located on the upper surface of the first transmission layer OL1. The second light-blocking patterns LBP2 may be spaced apart from each other in the second direction DR2. Some of the second light-blocking patterns LBP2 may be adjacent to the light-emitting layer EML in the second direction DR2 in a plan view. Other portions of the second light-blocking patterns LBP2 may be adjacent to the light-emitting layer EML in the direction opposite to the second direction DR2 in a plan view. The second light-blocking patterns LBP2 may block light. In one or more embodiments, a second width of the second light-blocking pattern LBP2 may be substantially the same as the first width of the first light-blocking pattern LBP1.

In one or more embodiments, the second width of the second light-blocking pattern LBP2 may be greater than a second thickness of the second light-blocking pattern LBP2. However, the present disclosure is not limited thereto, and the second width of the second light-blocking pattern LBP2 may be less than the second thickness of the second light-blocking pattern LBP2.

The second light-blocking pattern LBP2 may be shifted in the second direction DR2 from the first light-blocking pattern LBP1. Accordingly, a side surface of the second light-blocking pattern LBP2 may be shifted in the second direction DR2 from a side surface of the first light-blocking pattern LBP1. The second light-blocking pattern LBP2 may partially overlap the first light-blocking pattern LBP1 in a plan view. An imaginary straight line IML, which connects the side surface of the first light-blocking pattern LBP1 and the side surface of the second light-blocking pattern LBP2, may be tilted by a second angle AGL2 in the second direction DR2 with respect to the first normal line N1. In one or more embodiments, a difference between the first angle AGL1 and the second angle AGL2 may be about 0 degrees to about 2 degrees. For example, the first angle AGL1 and the second angle AGL2 may be substantially equal to each other. In this case, the imaginary straight line IML may be substantially parallel to the second normal line N2.

The second transmission layer OL2 may be located on the first transmission layer OL1. The second transmission layer OL2 may cover the second light-blocking patterns LBP2, and may have a substantially flat upper surface. The second transmission layer OL2 may have a refractive index that is greater than 1. The second transmission layer OL2 may include an organic material. For example, a thickness of the second transmission layer OL2 may be greater than the second thickness of the second light-blocking pattern LBP2. However, the present disclosure is not limited thereto, and the thickness of the second transmission layer OL2 may be substantially the same as the second thickness of the second light-blocking pattern LBP2.

The third light-blocking patterns LBP3 may be located on the second light-blocking patterns LBP2. For example, the third light-blocking patterns LBP3 may be located on the upper surface of the second transmission layer OL2. The third light-blocking patterns LBP3 may be spaced apart from each other in the second direction DR2. Some of the third light-blocking patterns LBP3 may be adjacent to the light-emitting layer EML in the second direction DR2 in a plan view. Other portions of the third light-blocking patterns LBP3 may be adjacent to the light-emitting layer EML in the direction opposite to the second direction DR2 in a plan view. The third light-blocking patterns LBP3 may block light. In one or more embodiments, a third width of the third light-blocking pattern LBP3 may be substantially the same as the first width of the first light-blocking pattern LBP1 and as the second width of the second light-blocking pattern LBP2.

In one or more embodiments, the third width of the third light-blocking pattern LBP3 may be greater than a third thickness of the third light-blocking pattern LBP3. However, the present disclosure is not limited thereto, and the third width of the third light-blocking pattern LBP3 may be less than the third thickness of the third light-blocking pattern LBP3.

The third light-blocking pattern LBP3 may be shifted in the second direction DR2 from the second light-blocking pattern LBP2. Accordingly, a side surface of the third light-blocking pattern LBP3 may be shifted in the second direction DR2 from the side surface of the second light-blocking pattern LBP2.

The imaginary straight line IML, which connects the side surface of the first light-blocking pattern LBP1, the side surface of the second light-blocking pattern LBP2, and the side surface of the third light-blocking pattern LBP3, may be tilted by the second angle AGL2 in the second direction DR2 with respect to the first normal line N1. In one or more embodiments, a first interval at which the second light-blocking pattern LBP2 is shifted from the first light-blocking pattern LBP1 may be substantially the same as a second interval at which the third light-blocking pattern LBP3 is shifted from the second light-blocking pattern LBP2.

The third transmission layer OL3 may be located on the second transmission layer OL2. The third transmission layer OL3 may cover the third light-blocking patterns LBP3, and may have a substantially flat upper surface. The third transmission layer OL3 may have a refractive index that is greater than 1. The third transmission layer OL3 may include an organic material. For example, a thickness of the third transmission layer OL3 may be greater than the third thickness of the third light-blocking pattern LBP3. However, the present disclosure is not limited thereto, and the thickness of the third transmission layer OL3 may be substantially the same as the third thickness of the third light-blocking pattern LBP3.

The fourth light-blocking patterns LBP4 may be located on the third light-blocking patterns LBP3. For example, the fourth light-blocking patterns LBP4 may be located on the upper surface of the third transmission layer OL3. The fourth light-blocking patterns LBP4 may be spaced apart from each other in the second direction DR2. Some of the fourth light-blocking patterns LBP4 may be adjacent to the light-emitting layer EML in the second direction DR2 in a plan view. Other portions of the fourth light-blocking patterns LBP4 may be adjacent to the light-emitting layer EML in the direction opposite to the second direction DR2 in a plan view. The fourth light-blocking patterns LBP4 may block light. In one or more embodiments, a fourth width of the fourth light-blocking pattern LBP4 may be substantially the same as the first width of the first light-blocking pattern LBP1, as the second width of the second light-blocking pattern LBP2, and as the third width of the third light-blocking pattern LBP3.

In one or more embodiments, the fourth width of the fourth light-blocking pattern LBP4 may be greater than a fourth thickness of the fourth light-blocking pattern LBP4. However, the present disclosure is not limited thereto, and the fourth width of the fourth light-blocking pattern LBP4 may be less than the fourth thickness of the fourth light-blocking pattern LBP4.

The fourth light-blocking pattern LBP4 may be shifted in the second direction DR2 from the third light-blocking pattern LBP3. Accordingly, a side surface of the fourth light-blocking pattern LBP4 may be shifted in the second direction DR2 from the side surface of the third light-blocking pattern LBP3.

The imaginary straight line IML, which connects the side surface of the first light-blocking pattern LBP1, the side surface of the second light-blocking pattern LBP2, the side surface of the third light-blocking pattern LBP3, and the side surface of the fourth light-blocking pattern LBP4, may be tilted by the second angle AGL2 in the second direction DR2 with respect to the first normal line N1. In one or more embodiments, a third interval at which the fourth light-blocking pattern LBP4 is shifted from the third light-blocking pattern LBP3 may be substantially the same as the first interval at which the second light-blocking pattern LBP2 is shifted from the first light-blocking pattern LBP1, and as the second interval at which the third light-blocking pattern LBP3 is shifted from the second light-blocking pattern LBP2.

For example, each of the first light-blocking pattern LBP1, the second light-blocking pattern LBP2, the third light-blocking pattern LBP3, and the fourth light-blocking pattern LBP4 may include chromium (Cr), molybdenum (Mo), chromium oxide (CrOₓ), molybdenum oxide (MoOₓ), carbon pigment, black resin, etc.

The fourth transmission layer OL4 may be located on the third transmission layer OL3. The fourth transmission layer OL4 may cover the fourth light-blocking patterns LBP4, and may have a substantially flat upper surface. The fourth transmission layer OL4 may have a refractive index that is greater than 1. The fourth transmission layer OL4 may include an organic material. For example, a thickness of the fourth transmission layer OL4 may be greater than the fourth thickness of the fourth light-blocking pattern LBP4. However, the present disclosure is not limited thereto, and the thickness of the fourth transmission layer OL4 may be substantially the same as the fourth thickness of the fourth light-blocking pattern LBP4.

A display device with an adjustable viewing angle may generally have a maximum luminance in the front direction of the display device (e.g., the third direction DR3). However, in some cases, it may be suitable to have a maximum luminance at a corresponding viewing angle.

The display device DD according to the first one or more embodiments of the present disclosure may have a maximum luminance at a corresponding viewing angle. To have a maximum luminance at the corresponding viewing angle, each of the pixel electrode PE and the light-emitting layer EML may be tilted by an angle (e.g., a predetermined angle) with respect to the horizontal plane of the substrate SUB. In other words, the light-emitting surface of the light-emitting layer EML may be tilted by an angle (e.g., a predetermined angle) with respect to the horizontal plane. A direction in which the main light of the light-emitting layer EML travels may be substantially parallel to a direction perpendicular to said light-emitting surface.

The third normal line of the light-emitting surface may be tilted by an angle substantially equal to the first angle AGL1 in the second direction DR2 with respect to the first normal line N1. That is, the main light of the light-emitting layer EML may travel inside the display device DD in a direction tilted by the first angle AGL1 in the second direction DR2 with respect to the first normal line N1. The main light may be refracted at the upper surface of the fourth transmission layer OL4. In this case, because a refractive index of the fourth transmission layer OL4 is greater than 1, the main light may travel outside the display device DD in a direction tilted by a first target angle α in the second direction DR2 with respect to a normal line of the upper surface of the fourth transmission layer OL4, angle α being greater than the first angle AGL1. The normal line of the upper surface of the fourth transmission layer OL4 may be parallel to the first normal line N1. For example, when the first angle AGL1 is about 6 degrees, the first target angle α may be about 10 degrees. However, the present disclosure is not limited thereto, and the first target angle α may change depending on the embodiments.

To have a maximum luminance at the corresponding viewing angle, and to adjust the viewing angle in the second direction DR2 and in the direction opposite to the second direction DR2, the light-blocking patterns LBP1, LBP2, LBP3, and LBP4 may be gradually shifted in the second direction DR2 as the distance from the light-emitting layer EML increases. In other words, the second light-blocking pattern LBP2 may be shifted in the second direction DR2 from the first light-blocking pattern LBP1, the third light-blocking pattern LBP3 may be shifted in the second direction DR2 from the second light-blocking pattern LBP2, and the fourth light-blocking pattern LBP4 may be shifted in the second direction DR2 from the third light-blocking pattern LBP3.

Referring further to FIG. 5, the light-blocking patterns LBP1, LBP2, LBP3, and LBP4 may block some of the light emitted from the light-emitting layer EML. In other words, the light-blocking patterns LBP1, LBP2, LBP3, and LBP4 may absorb and/or reflect some of the light emitted from the light-emitting layer EML to adjust the viewing angle of the display device DD. The light-blocking patterns LBP1, LBP2, LBP3, and LBP4 may adjust the viewing angle in the second direction DR2 and in the direction opposite to the second direction DR2. For example, the light-blocking patterns LBP1, LBP2, LBP3, and LBP4 may adjust the viewing angle in the upward direction and in the downward direction.

The imaginary straight line IML connecting the side surface of the first light-blocking pattern LBP1, the side surface of the second light-blocking pattern LBP2, the side surface of the third light-blocking pattern LBP3, and the side surface of the fourth light-blocking pattern LBP4 may be tilted by the second angle AGL2 in the second direction DR2 with respect to the first normal line N1. Accordingly, the light-blocking patterns LBP1, LBP2, LBP3, and LBP4 may adjust the viewing angle in the second direction DR2 and/or in the direction opposite to the second direction DR2 relative to a reference line SL. Here, the reference line SL may refer to an imaginary straight line tilted by a second target angle β in the second direction DR2 with respect to the normal line of the upper surface of the fourth transmission layer OL4. Because the refractive index of the fourth transmission layer OL4 is greater than 1, the second target angle β may be greater than the second angle AGL2. For example, when the second angle AGL2 is about 6 degrees, the second target angle β may be about 10 degrees.

However, the present disclosure is not limited thereto, and the second target angle β may change depending on the embodiments. In one or more embodiments, a difference between the first angle AGL1 and the second angle AGL2 may be about 0 1 degrees to about 2 degrees. For example, the first angle AGL1 and the second angle AGL2 may be substantially equal to each other.

For example, the light-blocking patterns LBP1, LBP2, LBP3, and LBP4 may block light that is refracted at an angle that is greater than a third angle AGL3 in the second direction DR2 relative to the reference line SL. In other words, the light-blocking patterns LBP1, LBP2, LBP3, and LBP4 may block light that is refracted at an angle that is greater than a first composite angle AGL3+β in the second direction DR2 relative to the first normal line N1. The first composite angle AGL3+β may be defined as an angle obtained by adding the second target angle β and the third angle AGL3.

The transmission layers OL1, OL2, OL3, and OL4 may transmit light that is refracted at an angle that is less than or equal to the third angle AGL3 in the second direction DR2 relative to the reference line SL to the outside of the display device DD. In other words, the transmission layers OL1, OL2, OL3, and OL4 may transmit light that is refracted at an angle that is less than or equal to the first composite angle AGL3+β in the second direction DR2 relative to the first normal line N1 to the outside of the display device DD. For example, the third angle AGL3 may be about 35 degrees. However, the present disclosure is not limited thereto, and the third angle AGL3 may change depending on the embodiments.

In addition, the light-blocking patterns LBP1, LBP2, LBP3, and LBP4 may block light that is refracted at an angle that is greater than the third angle AGL3 in the direction opposite to the second direction DR2 relative to the reference line SL. In other words, the light-blocking patterns LBP1, LBP2, LBP3, and LBP4 may block light that is refracted at an angle that is greater than a second composite angle AGL3−β in the direction opposite to the second direction DR2 relative to the first normal line N1. The second composite angle AGL3−β may be defined as an angle obtained by subtracting the second target angle β from the third angle AGL3.

The transmission layers OL1, OL2, OL3, and OL4 may transmit light that is refracted at an angle that is less than or equal to the third angle AGL3 in the direction opposite to the second direction DR2 relative to the reference line SL to the outside of the display device DD. In other words, the transmission layers OL1, OL2, OL3, and OL4 may transmit light that is refracted at an angle that is less than or equal to the second composite angle AGL3−β in the direction opposite to the second direction DR2 relative to the first normal line N1 to the outside of the display device DD.

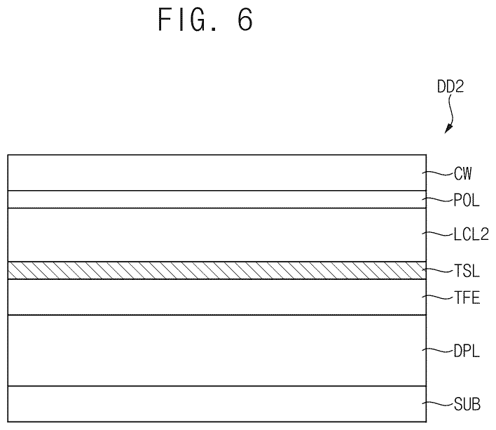

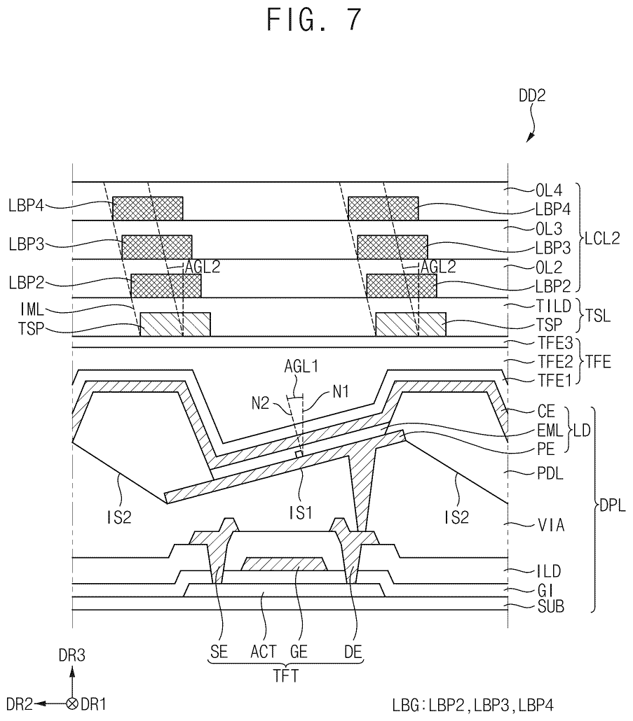

FIGS. 6 and 7 are cross-sectional views illustrating a display device according to a second one or more embodiments of the present disclosure.

Referring to FIG. 6, a display device DD2 according to a second one or more embodiments of the present disclosure may include the substrate SUB, the display element layer DPL, the encapsulation layer TFE, a sensing layer TSL, a second light control layer LCL2, the polarization layer POL, and the cover window CW.

The display device DD2 may be substantially the same as the display device DD described above with reference to FIG. 3, except that the display device DD2 includes the sensing layer TSL and the second light control layer LCL2. Hereinafter, redundant descriptions of the display device DD described above with reference to FIG. 3 may be omitted or may be summarized.

The sensing layer TSL may be located on the encapsulation layer TFE. The sensing layer TSL may detect a user's touch. For example, the sensing layer TSL may acquire coordinate information based on an external input, such as the user's touch. For example, the sensing layer TSL may acquire coordinate information according to an external input using a mutual capacitance method and/or a self-capacitance method. The sensing layer TSL may include a plurality of sensing patterns, routing lines connected to the corresponding sensing patterns, and at least one sensing insulating layer.

The second light control layer LCL2 may be located on the sensing layer TSL. The second light control layer LCL2 may include a plurality of transmission layers and a plurality of light-blocking patterns. The light-blocking patterns may block light that is refracted at an angle that is greater than an angle (e.g., a predetermined angle). The transmission layers may transmit light that is refracted at an angle that is less than or equal to the angle (e.g., the predetermined angle) to the outside of the display device DD2. Accordingly, the viewing angle of the display device DD2 may be adjusted.

Referring to FIG. 7, the display device DD2 according to the second one or more embodiments of the present disclosure may include the substrate SUB, the display element layer DPL, the encapsulation layer TFE, the sensing layer TSL, and the second light control layer LCL2. The sensing layer TSL may include a plurality of sensing patterns TSP and a sensing insulating layer TILD. The second light control layer LCL2 may include the second light-blocking patterns LBP2, the second transmission layer OL2, the third light-blocking patterns LBP3, the third transmission layer OL3, the fourth light-blocking patterns LBP4, and the fourth transmission layer OL4.

The display device DD2 may be substantially the same as the display device DD described above with reference to FIGS. 4 and 5, except that the sensing patterns TSP may perform a light-blocking function, and may be utilized as a light-blocking pattern. Hereinafter, redundant descriptions of the display device DD described above with reference to FIGS. 4 and 5 may be omitted or may be summarized.

The sensing patterns TSP may be located on the encapsulation layer TFE. The sensing patterns TSP may be spaced apart from each other in the second direction DR2. Some of the sensing patterns TSP may be adjacent to the light-emitting layer EML in the second direction DR2 in a plan view. Other portions of the sensing patterns TSP may be adjacent to the light-emitting layer EML in the direction opposite to the second direction DR2 in a plan view.

Each of the sensing patterns TSP may include a metal. For example, each of the sensing patterns TSP may include chromium (Cr), molybdenum (Mo), titanium (Ti), aluminum (Al), etc. Accordingly, the sensing patterns TSP may block light. In other words, the sensing patterns TSP may be utilized as a light-blocking pattern. That is, the sensing patterns TSP may replace some of the light-blocking patterns LBP1, LBP2, LBP3, and LBP4, which are illustrated in FIG. 4.

In one or more embodiments, a width of the sensing pattern TSP may be greater than a thickness of the sensing pattern TSP. However, the present disclosure is not limited thereto, and the width of the sensing pattern TSP may be less than the thickness of the sensing pattern TSP.

The sensing insulating layer TILD may be located on the encapsulation layer TFE. The sensing insulating layer TILD may cover the sensing patterns TSP, and may have a substantially flat upper surface. The sensing insulating layer TILD may have a refractive index that is greater than 1. The sensing insulating layer TILD may include an organic insulating material. For example, a thickness of the sensing insulating layer TILD may be greater than the thickness of the sensing pattern TSP. However, the present disclosure is not limited thereto, and the thickness of the sensing insulating layer TILD may be substantially the same as the thickness of the sensing pattern TSP.

The second light-blocking patterns LBP2 may be located on the sensing patterns TSP. For example, the second light-blocking patterns LBP2 may be located on the upper surface of the sensing insulating layer TILD. In one or more embodiments, a second width of the second light-blocking patterns LBP2 may be substantially the same as the width of the sensing pattern TSP.

The second light-blocking pattern LBP2 may be shifted in the second direction DR2 from the sensing pattern TSP. In other words, the sensing pattern TSP may be shifted in the direction opposite to the second direction DR2 from the second light-blocking pattern LBP2. Accordingly, a side surface of the second light-blocking pattern LBP2 may be shifted in the second direction DR2 from a side surface of the sensing pattern TSP. An imaginary straight line IML, which connects the side surface of the sensing pattern TSP and the side surface of the second light-blocking pattern LBP2, may be tilted by the second angle AGL2 in the second direction DR2 with respect to the first normal line N1. The second light-blocking pattern LBP2 may partially overlap the sensing pattern TSP in a plan view.

The third light-blocking patterns LBP3 may be located on the second light-blocking patterns LBP2. For example, the third light-blocking patterns LBP3 may be located on the upper surface of the second transmission layer OL2. The third light-blocking pattern LBP3 may be shifted in the second direction DR2 from the second light-blocking pattern LBP2. Accordingly, a side surface of the third light-blocking pattern LBP3 may be shifted in the second direction DR2 from the side surface of the second light-blocking pattern LBP2.

The fourth light-blocking patterns LBP4 may be located on the third light-blocking patterns LBP3. For example, the fourth light-blocking patterns LBP4 may be located on the upper surface of the third transmission layer OL3. The fourth light-blocking pattern LBP4 may be shifted in the second direction DR2 from the third light-blocking pattern LBP3. Accordingly, a side surface of the fourth light-blocking pattern LBP4 may be shifted in the second direction DR2 from the side surface of the third light-blocking pattern LBP3.

The imaginary straight line IML connecting the side surface of the sensing pattern TSP, the side surface of the second light-blocking pattern LBP2, the side surface of the third light-blocking pattern LBP3, and the side surface of the fourth light-blocking pattern LBP4 may be tilted by the second angle AGL2 in the second direction DR2 with respect to the first normal line N1. In one or more embodiments, a third interval at which the fourth light-blocking pattern LBP4 is shifted from the third light-blocking pattern LBP3 may be substantially the same as a first interval at which the second light-blocking pattern LBP2 is shifted from the sensing pattern TSP and a second interval at which the third light-blocking pattern LBP3 is shifted from the second light-blocking pattern LBP2.

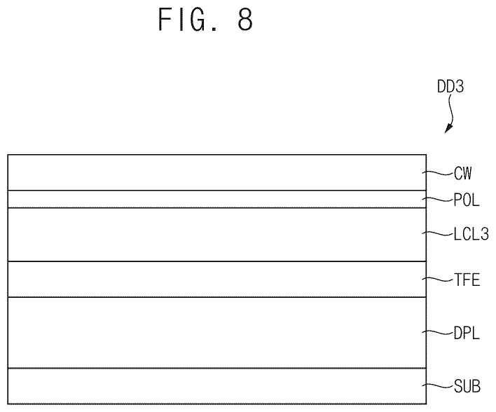

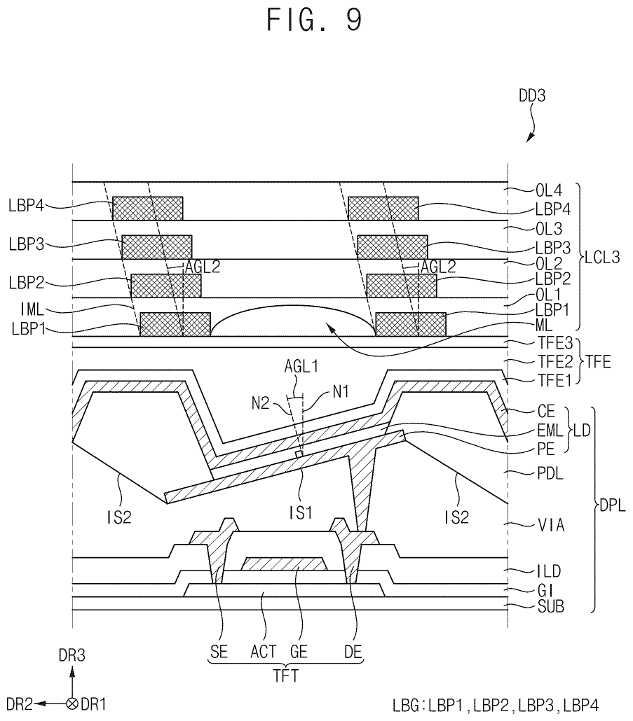

FIGS. 8 and 9 are cross-sectional views illustrating a display device according to a third one or more embodiments of the present disclosure.

Referring to FIGS. 8 and 9, a display device DD3 according to a third one or more embodiments of the present disclosure may include the substrate SUB, the display element layer DPL, the encapsulation layer TFE, a third light control layer LCL3, the polarization layer POL, and the cover window CW. The third light control layer LCL3 may be located on the encapsulation layer TFE. The third light control layer LCL3 may include the first to fourth light-blocking patterns LBP1, LBP2, LBP3, and LBP4, the first to fourth transmission layers OL1, OL2, OL3, and OL4, and a micro lens portion ML.

The display device DD3 may be substantially the same as the display device DD described above with reference to FIGS. 3, 4, and 5, except that the third light control layer LCL3 further includes the micro lens portion ML. Hereinafter, redundant descriptions of the display device DD described above with reference to FIGS. 3, 4, and 5 may be omitted or may be summarized.

The micro lens portion ML may be located on the encapsulation layer TFE. The micro lens portion ML may overlap the light-emitting layer EML in a plan view. The micro lens portion ML may improve light extraction efficiency. The micro lens portion ML may have a refractive index (e.g., a predetermined refractive index). For example, the micro lens portion ML may have a refractive index of more than about 1.5 and less than about 1.7, but the present disclosure is not limited thereto.

In one or more embodiments, the micro lens portion ML may be located at a lower portion of the third light control layer LCL3. For example, as illustrated in FIG. 9, the micro lens portion ML may be located between the first light-blocking patterns LBP1. That is, the micro lens portion ML may be located between the first light-blocking patterns LBP1 positioned closest to the light-emitting layer EML among the light-blocking patterns LBP1, LBP2, LBP3, and LBP4. In this case, the first light-blocking patterns LBP1 may be spaced apart from each other in the second direction DR2 with the micro lens portion ML interposed therebetween. However, the present disclosure is not limited thereto, and the micro lens portion ML may be located between the second light-blocking patterns LBP2.

In one or more embodiments, the micro lens portion ML may be located at an upper portion of the third light control layer LCL3. For example, the micro lens portion ML may be located between the fourth light-blocking patterns LBP4. For example, the micro lens portion ML may be located between the fourth light-blocking patterns LBP4 positioned closest to the outside of the display device DD3 among the light-blocking patterns LBP1, LBP2, LBP3, and LBP4. In this case, the fourth light-blocking patterns LBP4 may be spaced apart from each other in the second direction DR2 with the micro lens portion ML interposed therebetween. However, the present disclosure is not limited thereto, and the micro lens portion ML may be located between the third light-blocking patterns LBP3.

The first transmission layer OL1 may be located on the encapsulation layer TFE. The first transmission layer OL1 may cover the first light-blocking patterns LBP1 and the micro lens portion ML, and may have a substantially flat upper surface. The first transmission layer OL1 may include an organic material. The first transmission layer OL1 may have a refractive index that is greater than 1. In one or more embodiments, a refractive index of the first transmission layer OL1 may be less than a refractive index of the micro lens portion ML. For example, the first transmission layer OL1 may have a refractive index of more than about 1.2 and less than about 1.4, but the present disclosure is not limited thereto.

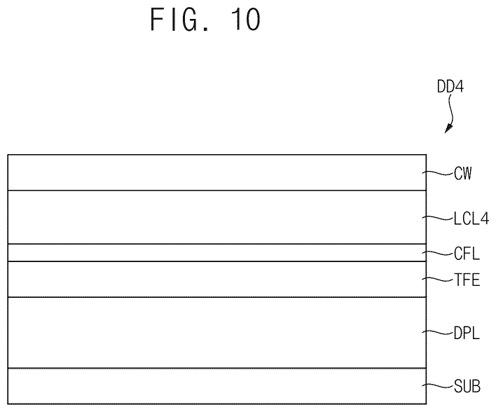

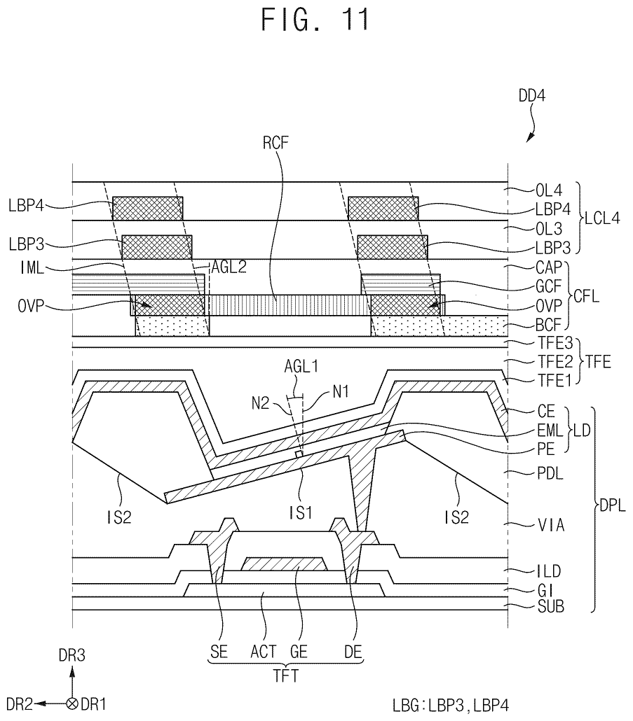

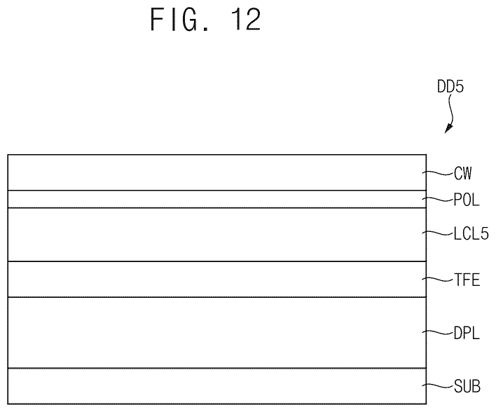

FIGS. 10 and 11 are cross-sectional views illustrating a display device according to a fourth one or more embodiments of the present disclosure.

Referring to FIG. 10, a display device DD4 according to a fourth one or more embodiments of the present disclosure may include the substrate SUB, the display element layer DPL, the encapsulation layer TFE, a color filter layer CFL, a fourth light control layer LCL4, and the cover window CW.

The display device DD4 may be substantially the same as the display device DD described above with reference to FIG. 3, except that the display device DD4 includes the color filter layer CFL and the fourth light control layer LCL4, and does not include the polarization layer POL, which is illustrated in FIG. 3. Hereinafter, redundant descriptions of the display device DD described above with reference to FIG. 3 may be omitted or may be summarized.

The color filter layer CFL may be located on the encapsulation layer TFE. The color filter layer CFL may include a plurality of color filters. The color filters may block light corresponding to a corresponding wavelength range. In addition, the color filters may reduce external light reflection. As the color filter layer CFL includes the color filters, the display device DD4 may not include the polarization layer POL, which is illustrated in FIG. 3.

The fourth light control layer LCL4 may be located on the color filter layer CFL. The fourth light control layer LCL4 may include a plurality of transmission layers and a plurality of light-blocking patterns. The light-blocking patterns may block light that is refracted at an angle that is greater than an angle (e.g., a predetermined angle). The transmission layers may transmit light that is refracted at an angle that is less than or equal to the angle (e.g., the predetermined angle) to the outside of the display device DD4. Accordingly, the viewing angle of the display device DD4 may be adjusted.

Referring to FIG. 11, the display device DD4 according to the fourth one or more embodiments of the present disclosure may include the substrate SUB, the display element layer DPL, the encapsulation layer TFE, the color filter layer CFL, and the fourth light control layer LCL4. The color filter layer CFL may include a first color filter RCF, a second color filter GCF, a third color filter BCF, and a capping layer CAP. The fourth light control layer LCL4 may include the third light-blocking patterns LBP3, the third light transmission layer OL3, the fourth light-blocking patterns LBP4, and the fourth light transmission layer OL4.

The display device DD4 may be substantially the same as the display device DD described above with reference to FIGS. 4 and 5, except that an overlapping pattern OVP defined by the first to third color filters RCF, GCF, and BCF overlapping each other in a plan view may perform a light-blocking function, and may be utilized as a light-blocking pattern. Hereinafter, redundant descriptions of the display device DD described above with reference to FIGS. 4 and 5 may be omitted or may be summarized.

The first to third color filters RCF, GCF, and BCF may be located on the encapsulation layer TFE. The first to third color filters RCF, GCF, and BCF may transmit different colors of light. For example, the first color filter RCF may transmit red light, the second color filter GCF may transmit green light, and the third color filter BCF may transmit blue light. However, the present disclosure is not limited thereto. The first color filter RCF may overlap the light-emitting layer EML in a plan view.

The color filter layer CFL may further include the overlapping pattern OVP. The overlapping pattern OVP may be defined as a portion where the first color filter RCF, the second color filter GCF, and the third color filter BCF overlap each other in a plan view. The overlapping pattern OVP may block light. In other words, the overlapping pattern OVP may be utilized as a light-blocking pattern. That is, the overlapping pattern OVP may replace some of the light-blocking patterns LBP1, LBP2, LBP3, and LBP4, which are illustrated in FIG. 4.

The capping layer CAP may be located on the encapsulation layer TFE. The capping layer CAP may cover the first to third color filters RCF, GCF, and BCF, and may have a substantially flat upper surface. That is, the capping layer CAP may flatten a step difference formed by the first to third color filters RCF, GCF, and BCF. The capping layer CAP may include an organic insulating material. The capping layer CAP may have a refractive index that is greater than 1.

The third light-blocking patterns LBP3 may be located on the capping layer CAP. For example, the third light-blocking patterns LBP3 may be located on the upper surface of the capping layer CAP. The third light-blocking pattern LBP3 may be shifted in the second direction DR2 from the overlapping pattern OVP. In other words, the overlapping pattern OVP may be shifted in the direction opposite to the second direction DR2 from the third light-blocking pattern LBP3. Accordingly, a side surface of the third light-blocking pattern LBP3 may be shifted in the second direction DR2 from a side surface of the overlapping pattern OVP. An imaginary straight line IML connecting the side surface of the overlapping pattern OVP and the side surface of the third light-blocking pattern LBP3 may be tilted by the second angle AGL2 in the second direction DR2 with respect to the first normal line N1. The third light-blocking pattern LBP3 may partially overlap the overlapping pattern OVP in a plan view.

The fourth light-blocking patterns LBP4 may be located on the third light-blocking patterns LBP3. For example, the fourth light-blocking patterns LBP4 may be located on the upper surface of the third transmission layer OL3. The fourth light-blocking pattern LBP4 may be shifted in the second direction DR2 from the third light-blocking pattern LBP3. Accordingly, a side surface of the fourth light-blocking pattern LBP4 may be shifted in the second direction DR2 from the side surface of the third light-blocking pattern LBP3.

The imaginary straight line IML connecting the side surface of the overlapping pattern OVP, the side surface of the third light-blocking pattern LBP3, and the side surface of the fourth light-blocking pattern LBP4 may be tilted by the second angle AGL2 in the second direction DR2 with respect to the first normal line N1.

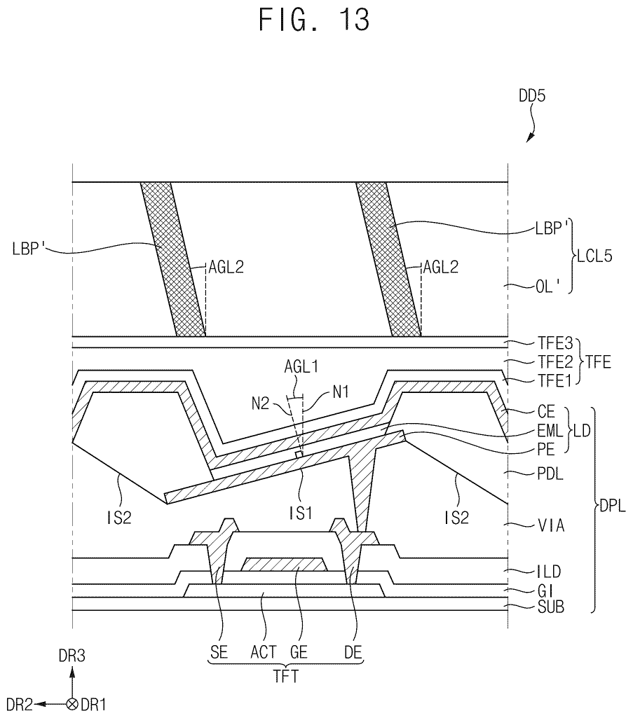

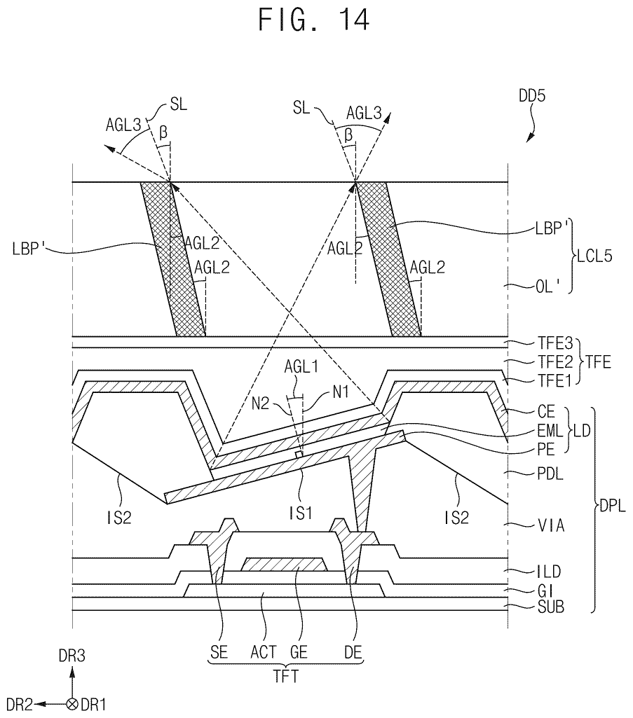

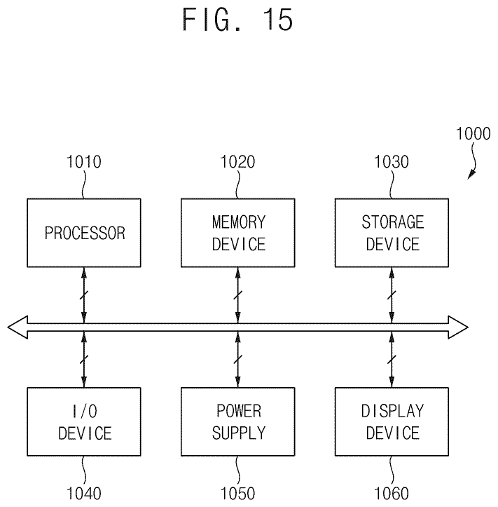

FIGS. 12 and 13 are cross-sectional views illustrating a display device according to a fifth one or more embodiments of the present disclosure. FIG. 14 is a cross-sectional view illustrating a path of light traveling in the display device of FIG. 13.

Referring to FIGS. 12 and 13, a display device DD5 according to a fifth one or more embodiments of the present disclosure may include the substrate SUB, the display element layer DPL, the encapsulation layer TFE, a fifth light control layer LCL5, the polarization layer POL, and the cover window CW. The fifth light control layer LCL5 may be located on the encapsulation layer TFE. The fifth light control layer LCL5 may include a plurality of light-blocking patterns LBP′ and a transmission layer OL′.

The display device DD5 may be substantially the same as the display device DD described above with reference to FIGS. 3, 4, and 5, except that the fifth light control layer LCL5 may include the light-blocking pattern LBP′ having a side surface tilted in the second direction DR2 with respect to the first normal line N1. Hereinafter, redundant descriptions of the display device DD described above with reference to FIGS. 3, 4, and 5 may be omitted or may be summarized.

The light-blocking patterns LBP′ may be located on the encapsulation layer TFE. The light-blocking patterns LBP′ may be spaced apart from each other in the second direction DR2. Some of the light-blocking patterns LBP′ may be adjacent to the light-emitting layer EML in the second direction DR2 in a plan view. Other portions of the light-blocking patterns LBP′ may be adjacent to the light-emitting layer EML in the direction opposite to the second direction DR2 in a plan view. The light-blocking patterns LBP′ may block light. For example, each of the light-blocking patterns LBP′ may include chromium (Cr), molybdenum (Mo), chromium oxide (CrOₓ), molybdenum oxide (MoOₓ), carbon pigment, black resin, etc.

In one or more embodiments, a width of the light-blocking pattern LBP′ may be less than a thickness of the light-blocking pattern LBP′. However, the present disclosure is not limited thereto, and the width of the light-blocking pattern LBP′ may be greater than the thickness of the light-blocking pattern LBP′.

The transmission layer OL′ may be located on the encapsulation layer TFE. The transmission layer OL′ may cover the light-blocking patterns LBP′, and may have a substantially flat upper surface. The transmission layer OL′ may transmit light. The transmission light OL′ may have a refractive index that is greater than 1. The transmission layer OL′ may include an organic material. For example, a thickness of the transmission layer OL′ may be substantially the same as the thickness of the light-blocking pattern LBP′. However, the present disclosure is not limited thereto, and the thickness of the transmission layer OL′ may be greater than the thickness of the light-blocking pattern LBP′.

Referring further to FIG. 14, the light-blocking patterns LBP′ may block some of the light emitted from the light-emitting layer EML. In other words, the light-blocking patterns LBP′ may absorb and/or block some of the light emitted from the light-emitting layer EML to adjust the viewing angle of the display device DD5. The light-blocking patterns LBP′ may adjust the viewing angle in the second direction DR2 and in the direction opposite to the second direction DR2. For example, the light-blocking patterns LBP′ may adjust the viewing angle in the upward direction and in the downward direction.

The side surface of the light-blocking pattern LBP′ may be tilted in the second direction DR2 with respect to the first normal line N1. Here, the first normal line N1 may be perpendicular to the horizontal plane of the substrate SUB. For example, the side surface of the light-blocking pattern LBP′ may be tilted by the second angle AGL2 in the second direction DR2 with respect to the first normal line N1. Accordingly, the light-blocking pattern LBP′ may adjust the viewing angle in the second direction DR2 and/or in the direction opposite to the second direction DR2 relative to the reference line SL. Here, the reference line SL may refer to an imaginary straight line tilted by the second target angle β in the second direction DR2 with respect to a normal line of the upper surface of the transmission layer OL′. The normal line of the upper surface of the transmission layer OL′ may be parallel to the first normal line N1. Because the refractive index of the transmission layer OL′ is greater than 1, the second target angle β may be greater than the second angle AGL2. For example, when the second angle AGL2 is about 6 degrees, the second target angle β may be about 10 degrees. However, the present disclosure is not limited thereto, and the second target angle β may change depending on the embodiments.

In one or more embodiments, a difference between the first angle AGL1 and the second angle AGL2 may be about 0 degrees to about 2 degrees. Here, the first angle AGL1 may refer to an angle at which the second normal line N2 of the upper surface of the pixel electrode PE is tilted in the second direction DR2 with respect to the first normal line N1. For example, the first angle AGL1 and the second angle AGL2 may be substantially equal to each other.

For example, the light-blocking patterns LBP′ may block light that is refracted at an angle that is greater than the third angle AGL3 in the second direction DR2 relative to the reference line SL. In other words, the light-blocking patterns LBP′ may block light that is refracted at an angle that is greater than the first composite angle AGL3+β in the second direction DR2 relative to the first normal line N1. The first composite angle AGL3+β may be defined as an angle obtained by adding the second target angle β and the third angle AGL3.

The transmission layer OL′ may transmit light that is refracted at an angle that is less than or equal to the third angle AGL3 in the second direction DR2 relative to the reference line SL to the outside of the display device DD5. In other words, the transmission layer OL′ may transmit light that is refracted at an angle that is less than or equal to the first composite angle AGL3+β in the second direction DR2 relative to the first normal line N1 to the outside of the display device DD5.

In addition, the light-blocking patterns LBP′ may block light that is refracted at an angle that is greater than the third angle AGL3 in the direction opposite to the second direction DR2 relative to the reference line SL. In other words, the light-blocking patterns LBP′ may block light that is refracted at an angle that is greater than the second composite angle AGL3−β in the direction opposite to the second direction DR2 relative to the first normal line N1. The second composite angle AGL3−β may be defined as an angle obtained by subtracting the second target angle β from the third angle AGL3.

The transmission layer OL′ may transmit light that is refracted at an angle that is less than or equal to the third angle AGL3 in the direction opposite to the second direction DR2 relative to the reference line SL to the outside of the display device DD5. In other words, the transmission layer OL′ may transmit light that is refracted at an angle that is less than or equal to the second composite angle AGL3−β in the direction opposite to the second direction DR2 relative to the first normal line N1 to the outside of the display device DD5.

In one or more embodiments, the fifth light control layer LCL5 may further include a micro lens portion (e.g., the micro lens portion ML of FIG. 9). The micro lens portion may be located on the encapsulation layer TFE. The micro lens portion may be located between the light-blocking patterns LBP′. In this case, the light-blocking patterns LBP′ may be spaced apart from each other in the second direction DR2 with the micro lens portion interposed therebetween. The micro lens portion may overlap the light-emitting layer EML in a plan view. The micro lens portion may improve light extraction efficiency.

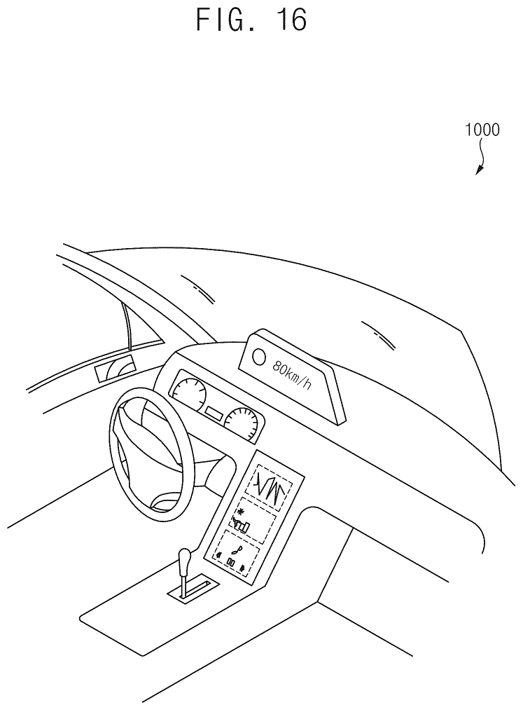

FIG. 15 is a block diagram illustrating an electronic device according to one or more embodiments of the present disclosure. FIG. 16 is a view illustrating an example of the electronic device of FIG. 15 is implemented as a window of automobile.

Referring to FIGS. 15 and 16, an electronic device 1000 may include a processor 1010, a memory device 1020, a storage device 1030, an input/output (I/O) device 1040, a power supply 1050, and a display device 1060. The display device 1060 may correspond to any one of the display device DD of FIG. 4, the display device DD2 of FIG. 7, the display device DD3 of FIG. 9, the display device DD4 of FIG. 11, and the display device DD5 of FIG. 13. In addition, the electronic device 1000 may further include a plurality of ports for communicating with a video card, a sound card, a memory card, a universal serial bus (USB) device, other systems, and the like.

In an embodiment, as illustrated in FIG. 16, the electronic device 1000 may be implemented as a window of automobile. However, the electronic device 1000 is not limited thereto. For example, the electronic device 1000 may be implemented as a smart pad, a smart watch, a tablet PC, a car navigation system, a smart phone, a computer monitor, a laptop, a head mounted display (“HMD”) device, and the like.

The processor 1010 may perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 may be coupled to an extended bus such as a peripheral component interconnection (“PCI”) bus.

The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 1060.

The power supply 1050 may provide power for operations of the electronic device 1000. In other words, the power supply 1050 may provide power to the display device 1060. The display device 1060 may be connected to other components through buses or other communication links.

The present disclosure may be applied to various display devices. For example, the present disclosure is applicable to various display devices, such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims, with functional equivalents thereof to be included therein.

1 what is claimed is:

1. A display device comprising:
a substrate;
a pixel electrode above the substrate, and having an upper surface tilted by an angle with respect to a plane of the substrate;
a light-emitting layer above the pixel electrode; and
a light control layer above the light-emitting layer, and comprising a first light-blocking pattern, and a second light-blocking pattern above the first light-blocking pattern and shifted in a first direction from the first light-blocking pattern.

2. The display device of claim 1, wherein a second normal line of the upper surface of the pixel electrode is tilted by a first angle in the first direction with respect to a first normal line of the plane,
wherein a side surface of the second light-blocking pattern is shifted in the first direction from a side surface of the first light-blocking pattern, and
wherein an imaginary straight line connecting the side surface of the first light-blocking pattern and the side surface of the second light-blocking pattern is tilted by a second angle in the first direction with respect to the first normal line.

3. The display device of claim 2, wherein a difference between the first angle and the second angle is about 0 degrees to about 2 degrees.

4. The display device of claim 1, wherein the light control layer further comprises a third light-blocking pattern above the second light-blocking pattern and shifted in the first direction from the second light-blocking pattern.

5. The display device of claim 4, wherein a first interval at which the second light-blocking pattern is shifted from the first light-blocking pattern is substantially equal to a second interval at which the third light-blocking pattern is shifted from the second light-blocking pattern.

6. The display device of claim 1, further comprising a via-insulating layer between the substrate and the pixel electrode, and comprising an inclined surface tilted by an angle with respect to the plane.

7. The display device of claim 1, further comprising a sensing pattern between the light-emitting layer and the light control layer, and comprising a metal, wherein the sensing pattern is shifted in a direction opposite to the first direction from the first light-blocking pattern.

8. The display device of claim 1, wherein the light control layer further comprises a micro lens portion overlapping the light-emitting layer in a plan view.

9. The display device of claim 8, wherein the first light-blocking pattern is provided in plural, the first light-blocking patterns being spaced apart from each other in the first direction with the micro lens portion interposed therebetween.

10. The display device of claim 8, wherein the second light-blocking pattern is provided in plural, the second light-blocking patterns being spaced apart from each other in the first direction with the micro lens portion interposed therebetween.

11. The display device of claim 1, further comprising a color filter layer between the light-emitting layer and the light control layer, and comprising a first color filter, a second color filter, and a third color filter that transmit light of different respective colors, and that have respective overlapping portions to form an overlapping pattern that is shifted in a direction opposite to the first direction from the first light-blocking pattern.

12. The display device of claim 1, wherein the light-emitting layer has a light-emitting surface that is tilted by an angle with respect to the plane, and that is substantially parallel to the upper surface of the pixel electrode.

13. The display device of claim 1, wherein the first light-blocking pattern and the second light-blocking pattern partially overlap in a plan view.

14. The display device of claim 1, wherein a length in the first direction of the first light-blocking pattern is substantially equal to a length in the first direction of the second light-blocking pattern.

15. A display device comprising:
a substrate;
a pixel electrode above the substrate, and having an upper surface tilted by an angle with respect to a plane of the substrate;
a light-emitting layer above the pixel electrode; and
a light control layer above the light-emitting layer, and comprising a light-blocking pattern having a side surface tilted in a first direction with respect to a first normal line of the plane.

16. The display device of claim 15, wherein a second normal line of the upper surface of the pixel electrode is tilted by a first angle in the first direction with respect to the first normal line, and
wherein the side surface of the light-blocking pattern is tilted by a second angle in the first direction with respect to the first normal line.

17. The display device of claim 16, wherein a difference between the first angle and the second angle is about 0 degrees to about 2 degrees.

18. The display device of claim 15, further comprising a via-insulating layer between the substrate and the pixel electrode, and comprising an inclined surface tilted by an angle with respect to the plane.

19. The display device of claim 15, wherein the light control layer further comprises a micro lens portion overlapping the light-emitting layer in a plan view, and
wherein the light-blocking pattern is provided in plural, the light-blocking patterns being spaced apart from each other in the first direction with the micro lens portion interposed therebetween.

20. The display device of claim 15, wherein the light-emitting layer has a light-emitting surface that is tilted by an angle with respect to the plane, and is substantially parallel to the upper surface of the pixel electrode.

21. An electronic device comprising:
a display device; and
a power supply configured to provide power to the display device,
wherein the display device comprises:
a substrate;
a pixel electrode above the substrate, and having an upper surface tilted by an angle with respect to a plane of the substrate;
a light-emitting layer above the pixel electrode; and
a light control layer above the light-emitting layer, and comprising a first light-blocking pattern, and a second light-blocking pattern above the first light-blocking pattern and shifted in a first direction from the first light-blocking pattern.
